(19) United States
(12) Patent Application Publication
(10) Pub. No.: US 2024/0339569 A1
(43) Pub. Date: Oct. 10, 2024

(54) LIGHT EMITTING DIODE AND LIGHT EMITTING DEVICE

(71) Applicant: Tianjin Sanan Optoelectronics Co., Ltd., Tianjin (CN)

(72) Inventors: Hong ZHENG, Tianjin (CN); Dongyan ZHANG, Tianjin (CN); Jingjuan LU, Tianjin (CN)

(73) Assignee: Tianjin Sanan Optoelectronics Co., Ltd., Tianjin (CN)

(21) Appl. No.: 18/624,080

(22) Filed: Apr. 1, 2024

(30) Foreign Application Priority Data
Apr. 7, 2023 (CN) 202310369255.4

(51) Int. Cl. H01L 33/38; H01L 33/10; H01L 33/42; H01L 33/52

(52) U.S. Cl. CPC H01L 33/387; H01L 33/10; H01L 33/382; H01L 33/42; H01L 33/52

(57) ABSTRACT

A light emitting diode includes an epitaxial structure, an N-type electrode, and a transparent conductive electrode. The epitaxial structure includes a P-type semiconductor layer, a light emitting layer, and an N-type semiconductor layer stacked sequentially. The N-type electrode is connected to the N-type semiconductor layer and includes a starting electrode and X extension electrodes, X≥2, the X extension electrodes are connected to the starting electrode, and the X extension electrodes are spaced apart along the edge of the starting electrode. The transparent conductive electrode is connected to the P-type semiconductor layer, wherein the transparent conductive electrode is a distributed electrode and includes Y independent surrounding electrodes, Y≥2, and Y≤X. A first projection of each surrounding electrode on a horizontal plane surrounds a second projection of an extension end of the extension electrode on the horizontal plane.

### CROSS-REFERENCE TO RELATED APPLICATION

This application claims the priority benefit of China application serial no. 202310369255.4, filed on Apr. 7, 2023. The entirety of the above-mentioned patent application is hereby incorporated by reference herein and made a part of this specification.

### BACKGROUND

### Technical Field

The disclosure relates to the field of semiconductor manufacturing technology, and particularly relates to a light emitting diode and a light emitting device.

### Description of Related Art

A light emitting diode (LED) is a semiconductor light emitting element, usually made of semiconductors such as GaN, GaAs, GaP, and GaAsP, and the core thereof is a PN junction with light emitting properties. LED has the advantages of high luminous intensity, high efficiency, small size, and long service life, and is considered to be one of the most promising light sources currently. LED has been widely used in fields such as lighting, monitoring and command, high-definition studio, high-end cinema, office display, conference interaction, and virtual reality.

At present, in order to improve product performance, vertical-structure light emitting diodes mainly use ITO electrodes to improve current expansion performance. However, the product performance of the existing ITO pattern design is poor. As shown in FIG. 1, the conventional ITO pattern design uses discrete distribution (the shaded portions in FIG. 1 are the ITO area), which cannot effectively improve the product performance of light emitting diodes, mainly manifested in high VF (forward voltage), poor ESD (electro-static discharge) protection performance, and poor current expansion performance in the near field. Therefore, how to optimize the ITO pattern design to improve the product performance of light emitting diodes has become one of the technical problems in this field that needs to be solved urgently.

The near field refers to the study of optical phenomena within a distance of one wavelength on the surface of an object (a light emitting diode), based on the detection and imaging principles of non-radiative fields, the study breaks through the diffraction limit of conventional optical microscopes and conducts nanoscale optical imaging and nanoscale spectral research at ultra-high optical resolution.

It should be noted that the information disclosed in this background section is only intended to increase understanding of the general background of the disclosure, and should not be regarded as an admission or in any form implying that the information constitutes related art known to persons of ordinary skill in the art.

### SUMMARY

An embodiment of the disclosure provides a light emitting diode, which includes an epitaxial structure, an N-type electrode, and a transparent conductive electrode. The epitaxial structure includes a P-type semiconductor layer, a light emitting layer, and an N-type semiconductor layer stacked sequentially. The N-type electrode is connected to the N-type semiconductor layer. The N-type electrode includes a starting electrode and X extension electrodes, in which X≥2 and is a positive integer. The X extension electrodes are connected to the starting electrode, and the X extension electrodes are spaced apart along the edge of the starting electrode. The transparent conductive electrode is connected to the P-type semiconductor layer. The transparent conductive electrode is a distributed electrode and includes Y surrounding electrodes independent to each other, Y≥2 and is a positive integer, and Y≤X. A first projection of each surrounding electrode on a horizontal plane surrounds a second projection of an extension end of the extension electrode on the horizontal plane.

In some embodiments, a portion of the surrounding electrode is between two adjacent extension electrodes. Preferably, the line segment connecting the extension ends of the two adjacent extension electrodes is defined as a connection line, and a distance of the surrounding electrode protruding from the connection line is in a range of 10 μm to 20 μm. If the distance is lower than the range, the distance between the surrounding electrode and the N-type electrode is too far, causing a decrease in the solderability of the light emitting diode; and if the distance is higher than the range, the distance between the surrounding electrode and the N-type electrode is too close, and the area occupied by the surrounding electrode is too large, causing the surrounding electrode to absorb too much light, which is not conducive to the light emission of the light emitting diode.

In some embodiments, the transparent conductive electrode is located on a side of the P-type semiconductor layer away from the light emitting layer, and the N-type electrode is located on a side of the N-type semiconductor layer away from the light emitting layer.

In some embodiments, the light emitting diode further includes a substrate, a blocking layer, a metal reflection layer, a P-type electrode, and an insulation layer. The blocking layer covers part of the transparent conductive electrode, the metal reflection layer covers the blocking layer and the transparent conductive electrode, the substrate is disposed on a side of the metal reflection layer away from the blocking layer, the P-type electrode is disposed on a side of the substrate away from the metal reflection layer, and the insulation layer encapsulates the epitaxial structure and the N-type electrode. Preferably, the material of the metal reflection layer includes at least one selected from a group comprising Ag, Au, and Al.

In some embodiments, a horizontal projection area of the transparent conductive electrode is 10% to 30% of a horizontal projection area of the epitaxial structure. If the proportion of the horizontal projection area of the transparent conductive electrode is more than 30%, the light absorption performance of the transparent conductive electrode is enhanced, which is not conducive to the light emission of the light emitting diode; and if the proportion of the horizontal projection area of the transparent conductive electrode is less than 10%, the design of the pattern of the transparent conductive electrode is limited, which causes the P-side ohmic contact area to be too small, thereby the driving voltage is increased.

In some embodiments, a third projection of the starting electrode on the horizontal plane is located at a center of a fourth projection of the epitaxial structure on the horizontal plane, and the third projection is quasicircular. The X extension electrodes include X1 short extension electrodes and X2 long extension electrodes, in which both X1 and X2 are positive integers, and X=X1+X2. A length of the long extension electrode is greater than a length of the short extension electrode. Preferably, considering current expansion and wiring issues, a shortest distance between the long extension electrode and the surrounding electrode is preferably in a range of 15 μm to 25 μm. If the distance between the two electrodes is too close, the current expansion is affected; and if the distance between the two electrodes is too far, the solderability performance of the light emitting diode is reduced.

In some embodiments, both X1 and X2 are greater than or equal to 2, and one short extension electrode is between two adjacent long extension electrodes. Preferably, the epitaxial structure has four sides, and the four sides are sequentially connected end to end to form four connection points, X1 and X2 are equal to 4, the four short extension electrodes respectively extend correspondingly to midpoints of the four sides of the epitaxial structure, and the four long extension electrodes respectively extend correspondingly to the four connection points.

In some embodiments, the first projection is in a hook shape, and the projection of the long extension electrode on the horizontal plane reaches deep into the interior of the first projection in the hook shape. Preferably, the reaching distance of the long extension electrode reaching into the first projection is 40% to 70% of the length of the long extension electrode. If the reaching distance is too large, the area of the long extension electrode will increase, which will affect the brightness of the light emitting diode due to the metal and epitaxial light absorption characteristics; if the reaching distance is too small, the extension end of the long extension electrode will be too far away from the surrounding electrode, which is not conducive to current expansion. In some embodiments, the reaching distance may be 20 μm to 40 μm.

In some embodiments, considering the extension arrangement of the long extension electrodes and the short extension electrodes and the design issue of the transparent conductive electrode, a side length of the light emitting diode is in a range of 150 μm to 300 μm.

An embodiment of the disclosure further provides a light emitting device, which adopts the light emitting diode provided in any of the above embodiments.

A light emitting diode and a light emitting device provided by an embodiment of the disclosure adopt the manner that the surrounding electrode surrounds the extension end of the extension electrode to improve the uniformity of the current expansion of the light emitting diode, which can effectively reduce the operating voltage of the light emitting diode, improve the ESD protection performance thereof, and improve the current expansion performance thereof in the near field, thereby the overall performance and quality of the light emitting diode are improved.

Other features and beneficial effects of the disclosure will be elaborated in the subsequent description, and some of the technical features and beneficial effects may be clearly obtained from the description, or may be understood by implementing the disclosure.

### BRIEF DESCRIPTION OF THE DRAWINGS

FIG. 1 is a schematic morphology view of a horizontal plane projection of a conventional light emitting diode.

FIG. 2 is a schematic morphology view of a horizontal plane projection of a light emitting diode provided by the first embodiment of the disclosure.

FIG. 3 is a schematic cross-sectional view taken along a section line F-F of FIG. 2.

FIG. 4 is an enlarged schematic view of an area A in FIG. 2.

FIG. 5 is a schematic morphology view of a horizontal plane projection of a light emitting diode provided by the second embodiment of the disclosure.

FIG. 6 is a schematic morphology view of a horizontal plane projection of a light emitting diode provided by the third embodiment of the disclosure.

FIG. 7 is a schematic view of current expansion of the light emitting diode of the disclosure under a near-field microscope.

FIG. 8 is a schematic view of current expansion of the conventional light emitting diode under the near-field microscope.

### DESCRIPTION OF THE EMBODIMENTS

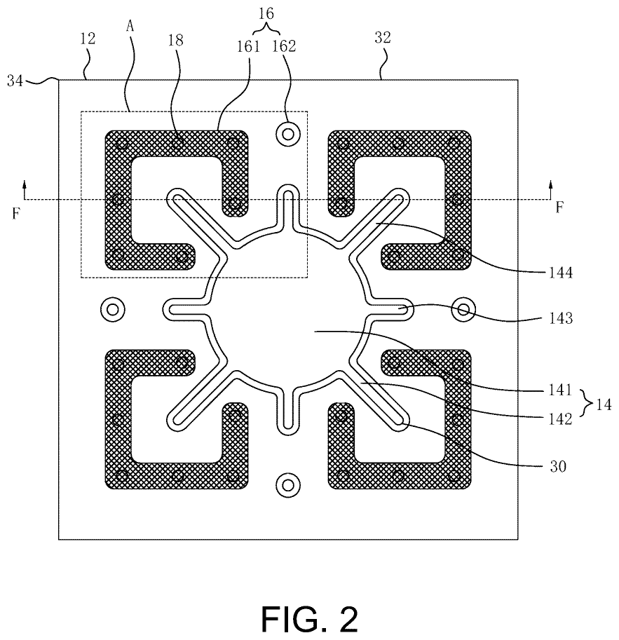

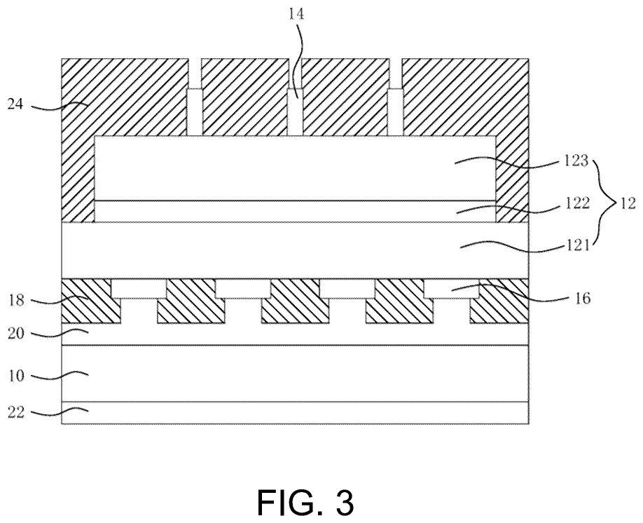

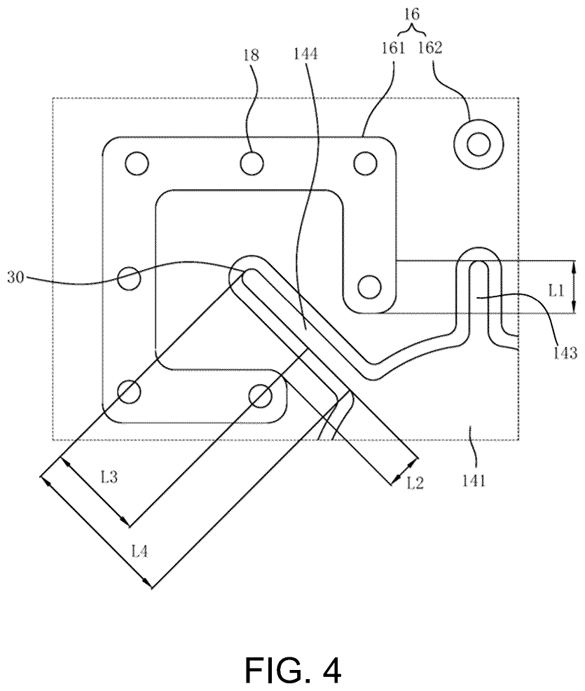

Please refer to FIG. 2, FIG. 3, and FIG. 4. FIG. 2 is a schematic morphology view of a horizontal plane projection of a light emitting diode provided by the first embodiment of the disclosure. FIG. 3 is a schematic cross-sectional view taken along a section line F-F of FIG. 2. FIG. 4 is an enlarged schematic view of an area A in FIG. 2. In order to achieve at least one of the above advantages or other advantages, the first embodiment of the disclosure provides the light emitting diode. As shown in the figure, the light emitting diode may include an epitaxial structure 12, an N-type electrode 14, and a transparent conductive electrode 16.

The epitaxial structure 12 includes a P-type semiconductor layer 121, a light emitting layer 122, and an N-type semiconductor layer 123 stacked sequentially.

The N-type semiconductor layer 123 may provide electrons to the light emitting layer 122 under the action of power. The N-type semiconductor layer 123 includes an N-type doped nitride layer, an arsenide layer, or a phosphide layer. N-type dopants may include one of Si, Ge, and Sn or a combination thereof. In some embodiments, the N-type semiconductor layer 123 includes an N-type cladding layer and an N-type window layer, and the N-type cladding layer is located between the N-type window layer and the light emitting layer 122. The material of the N-type cladding layer may include one of aluminum gallium indium phosphorus, gallium indium phosphorus, and aluminum indium phosphorus or a combination thereof. The material of the N-type window layer may include one of aluminum gallium indium phosphorus, gallium indium phosphorus, and aluminum indium phosphorus or a combination thereof.

The light emitting layer 122 may be a quantum well (QW) structure. In some embodiments, the light emitting layer 122 may also be a multiple quantum well (MQW) structure. The multiple quantum well structure includes multiple quantum well layers and multiple quantum barrier layers arranged alternately in a repetitive manner, for example, the structure may be a multiple quantum well structure of GaN/AlGaN, InAlGaN/InAlGaN, InGaN/AlGaN, or AlGaInP/AlGaInP. In addition, the composition and thickness of the well layer in the light emitting layer 122 determine the wavelength of the generated light. In order to improve the luminous efficiency of the light emitting layer 122, the improvement may be achieved by changing the depth of the quantum well, the number of layers of paired quantum well and quantum barrier, the thickness, and/or other characteristics in the light emitting layer 122.

The P-type semiconductor layer 121 may provide holes to the light emitting layer 122 under the action of power. The P-type semiconductor layer 121 includes a P-type doped nitride layer, an arsenide layer, or a phosphide layer. The P-type doped nitride layer, the arsenide layer, or the phosphide layer may include one or more P-type dopants. The P-type dopants may include one of Mg, Zn, and Be or a combination thereof. The P-type semiconductor layer 121 may be a single-layer structure or a multi-layer structure, and the multi-layer structure has different compositions. In addition, the setting of the epitaxial structure 12 is not limited to the description herein, and other types of epitaxial structure 12 may be selected according to actual needs.

The N-type electrode 14 is connected to the N-type semiconductor layer 123. The N-type electrode 14 may be a single-layer, double-layer, or multi-layer metal structure, for example, a laminated structure or an alloy structure such as Ti/Al, Ti/Al/Ti/Au, Ti/Al/Ni/Au, V/Al/Pt/Au, AuGe, and AuGeNi. The N-type electrode 14 includes a starting electrode 141 and X extension electrodes 142, in which X≥2 and is a positive integer. The X extension electrodes 142 are connected to the starting electrode 141, and the X extension electrodes 142 are spaced apart along the edge of the starting electrode 141. In the illustrated embodiment, the number X is eight, that is, eight extension electrodes 142 are evenly spaced along the edge of the starting electrode 141.

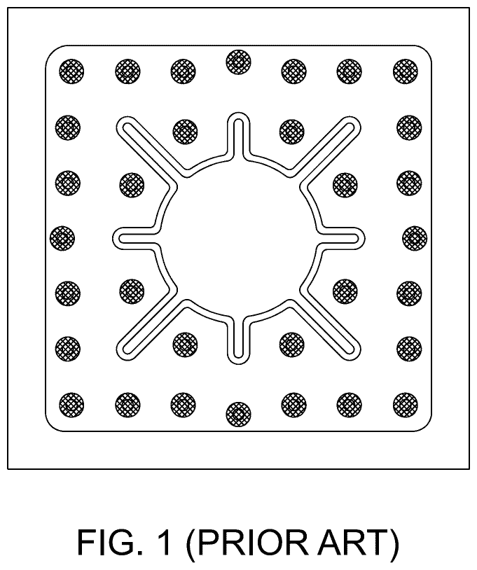

The transparent conductive electrode 16 is connected to the P-type semiconductor layer 121. The transparent conductive electrode 16 is a distributed electrode, and the transparent conductive electrode 16 includes Y surrounding electrodes 161 independent to each other, in which Y≥2 and is a positive integer, and Y≤X. The shaded portions in FIG. 2 are the surrounding electrodes 161. A first projection of each surrounding electrode 161 on the horizontal plane surrounds a second projection of an extension end 30 of the extension electrode 142 on the horizontal plane (as shown in FIG. 2). In other words, viewing from the projections of the horizontal plane, the extension end 30 of the extension electrode 142 reaches deep into an interior of the surrounding electrode 161. Compared with conventional ITO patterning, in the manner that the surrounding electrode 161 surrounds the extension end 30 of the extension electrode 142 according to the disclosure, the manner can effectively reduce the operating voltage of the light emitting diode, improve the ESD protection performance thereof, and improve the current expansion performance thereof in the near field, thereby the overall performance and quality of the light emitting diode are improved. Specifically, since the conventional ITO is designed in a manner of discrete circular holes (as shown in FIG. 1), when the power is on, the current around the extension electrode is more concentrated, and due to the small area of the ITO, the resistance value is higher, the outward conductivity of the current is poor, and the ESD capability is also poor. On the contrary, the disclosure increases the overall contact area by using the surrounding electrode 161 having a larger area compared to the conventional circular hole ITO, and arranging the surrounding electrode 161 to surround the extension end 30 of the extension electrode 142, the capability of current output outward along the pattern direction of the transparent conductive electrode 16 is increased, thereby the external conductivity is increased and the ESD capability is also improved.

The material of the transparent conductive electrode 16 is a transparent conductive material. The transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto.

In some embodiments, a portion of the surrounding electrode 161 is between two adjacent extension electrodes 142, and a head end and a tail end of each surrounding electrode 161 are located between the two adjacent extension electrodes 142. That is to say, a connection line between the extension ends 30 of the two adjacent extension electrodes 142 pass through the surrounding electrode 161. The line segment connecting the extension ends 30 of the two adjacent extension electrodes 142 is defined as a connection line. Preferably, a distance L1 of the surrounding electrode 161 protruding from the connection line is in a range of 10 μm to 20 μm. If the distance L1 is lower than the range, the distance between the surrounding electrode 161 and the N-type electrode 14 is too far, causing a decrease in the solderability of the light emitting diode; and if the distance L1 is higher than the range, the distance between the surrounding electrode 161 and the N-type electrode 14 is too close, and the area occupied by the surrounding electrode 161 is too large, causing the surrounding electrode 161 to absorb too much light, which is not conducive to the light emission of the light emitting diode.

The manner of the surrounding electrode 161 surrounding the extension end 30 of the extension electrode 142 is more suitable for vertical-structure light emitting diodes. The transparent conductive electrode 16 is located on a side of the P-type semiconductor layer 121 away from the light emitting layer 122, and the N-type electrodes 14 is located on a side of the N-type semiconductor layer 123 away from the light emitting layer 122, that is, the N-type electrode 14 and the transparent conductive electrode 16 are respectively located on the upper and lower sides of the light emitting layer 122.

The light emitting diode may further include a substrate 10, a blocking layer 18, a metal reflection layer 20, a P-type electrode 22, and an insulation layer 24.

The substrate 10 is sandwiched between the P-type electrode 22 and the metal reflection layer 20, that is, the substrate 10 is disposed on a side of the metal reflection layer 20 away from the blocking layer 18. A material of the substrate 10 may be a conductive material or a semiconductor material. For example, the material of the substrate 10 may include at least one of silicon carbide, silicon, magnesium aluminum oxide, magnesium oxide, lithium aluminum oxide, aluminum gallium oxide, and gallium nitride.

The blocking layer 18 covers part of the transparent conductive electrodes 16, and forms openings to expose part of the transparent conductive electrodes 16. A material of the blocking layer 18 is an insulation material. The insulation material may include, for example, aluminum oxide, silicon nitride, silicon oxide, titanium oxide, and magnesium fluoride. Circles located within the surrounding electrode 161 and bulk electrodes 162 in the drawing are the openings of the blocking layer 18.

The metal reflection layer 20 covers the blocking layer 18 and the transparent conductive electrode 16, and the metal reflection layer 20 is connected to the transparent conductive electrode 16 through the openings of the blocking layer 18. In addition to conducting electricity, the metal reflection layer 20 also plays a role in reflecting light. Preferably, the material of the metal reflection layer 20 includes at least one selected from a group comprising Ag, Au, and Al.

The P-type electrode 22 is disposed on a side of the substrate 10 away from the metal reflection layer 20. The P-type electrode 22 may be a single-layer, double-layer, or multi-layer metal structure.

The insulation layer 24 encapsulates the epitaxial structure 12 and the N-type electrode 14, and the insulation layer 24 forms openings to expose part of the N-type electrode 14. The material of the insulation layer 24 includes a non-conductive material. The non-conductive material is preferably an inorganic material or a dielectric material. The inorganic material may include silica gel. The dielectric material includes an electrically insulation material, for example, aluminum oxide, silicon nitride, silicon oxide, titanium oxide, or magnesium fluoride. For example, the insulation layer 24 may be silicon dioxide, silicon nitride, titanium oxide, tantalum oxide, niobium oxide, barium titanate, or a combination thereof.

In some embodiments, a horizontal projection area of the transparent conductive electrode 16 is 10% to 30% of a horizontal projection area of the epitaxial structure 12. If the proportion of the horizontal projection area of the transparent conductive electrode 16 is more than 30%, the light absorption performance of the transparent conductive electrode 16 is enhanced, which is not conducive to the light emission of the light emitting diode; and if the proportion of the horizontal projection area of the transparent conductive electrode 16 is less than 10%, the design of the pattern of the transparent conductive electrode 16 is limited, which causes the P-side ohmic contact area to be too small, thereby the driving voltage is increased.

In some embodiments, a third projection of the starting electrode 141 on the horizontal plane is located at a center of a fourth projection of the epitaxial structure 12 on the horizontal plane, and the third projection is quasicircular. That is, the starting electrode 141 is an electrode in a quasicircular shape and is disposed at the center of the epitaxial structure 12. The X extension electrodes 142 include X1 short extension electrodes 143 and X2 long extension electrodes 144, in which both X1 and X2 are positive integers, and X=X1+X2. A length L4 of the long extension electrode 144 is greater than a length of the short extension electrode 143. Considering current expansion and wiring issues, a shortest distance L2 between the long extension electrode 144 and the surrounding electrode 161 is preferably in a range of 15 μm to 25 μm. If the distance L2 between the two electrodes is too close, the brightness is affected by light absorption due to the large ITO area; and if the distance L2 between the two electrodes is too far, the solderability performance of the light emitting diode is reduced.

In some embodiments, both X1 and X2 are greater than or equal to 2, that is, the respective quantities of the short extension electrode 143 and the long extension electrode 144 are at least 2. One short extension electrode 143 is between two adjacent long extension electrodes 144. That is to say, the outer edge of the starting electrode 141 is formed in a manner that the extension electrodes 142 are distributed surroundingly in a “long-short-long-short” arrangement. Through this “long-short-long-short” distribution of the extension electrodes 142, the arrangement is conducive to current expansion, thereby the photoelectric performance of the light emitting diode can be further improved.

In this embodiment, the epitaxial structure 12 has four sides 32, and the four sides 32 are sequentially connected end to end to form four connection points 34, that is, each connection point 34 is formed by connecting two sides 32. X1 and X2 are equal to 4, that is, there are four short extension electrodes 143 and four long extension electrodes 144. The four short extension electrodes 143 respectively extend correspondingly to midpoints of the four sides 32 of the epitaxial structure 12, and the four long extension electrodes 144 respectively extend correspondingly to the four connection points 34. The surrounding electrode 161 surrounds the extension end 30 of the long extension electrode 144, and the arrangement is because the area between the short extension electrode 143 and the side 32 is limited. If the surrounding electrode 161 surrounds the short extension electrode 143, it is not conducive to current expansion. On the contrary, since the blank area at the long extension electrode 144 is larger, by surrounding the long extension electrode 144 with the surrounding electrode 161, the current expansion at the edge of the near field of the light emitting diode can be effectively increased.

Considering that the starting electrode 141 is located at the center, the current expansion effect at the edge is poor, the extension end 30 of the long extension electrode 144 and the extension end 30 of the short extension electrode 143 located on the same side 32 are aligned, so that the extension ends 30 of the two long extension electrodes 144 and the extension end 30 of the short extension electrode 143 sandwiched in the middle are on the same straight line to improve the current expansion effect at the edge, and thereby the photoelectric performance of the light emitting diode is improved.

In this embodiment, as shown in FIG. 4, the first projection is in a hook shape. The hook shape means that the “hook” shape is disconnected near the long extension electrode 144, so that the long extension electrode 144 reaches deep into the interior of the first projection in the hook shape from the disconnection place. A reaching distance L3 refers to a distance of the long extension electrode 144 extends toward the outer edge and protrudes beyond a boundary, in which the boundary is a shortest distance between a first end and a last end of the hook-shaped first projection. Preferably, the reaching distance L3 of the long extension electrode 144 reaching into the first projection is 40% to 70% of a length L4 of the long extension electrode 144. If the reaching distance L3 is too large (for example, greater than 70%), the extension end 30 of the long extension electrode 144 is too close to the surrounding electrode 161, resulting in an increase in the area of the long extension electrode 144, which affects the brightness of the light emitting diode due to the metal and epitaxial light absorption properties; and if the reaching distance L3 is too small (for example, less than 40%), the extension end 30 of the long extension electrode 144 is too far away from the surrounding electrode 161, which is not conducive to current expansion. In some embodiments, the reaching distance L3 may be in a range of 20 μm to 40 μm.

In addition to the surrounding electrode 161, the transparent conductive electrode 16 may further include other independent bulk electrodes 162. The independent bulk electrodes 162 are distributed at the edges, which can further improve the current expansion effect. In some embodiments, considering the disposition of the long extension electrode 144 and the short extension electrode 143 and the design issue of the transparent conductive electrode 16, a side length of the light emitting diode is preferably in a range of 150 μm to 300 μm.

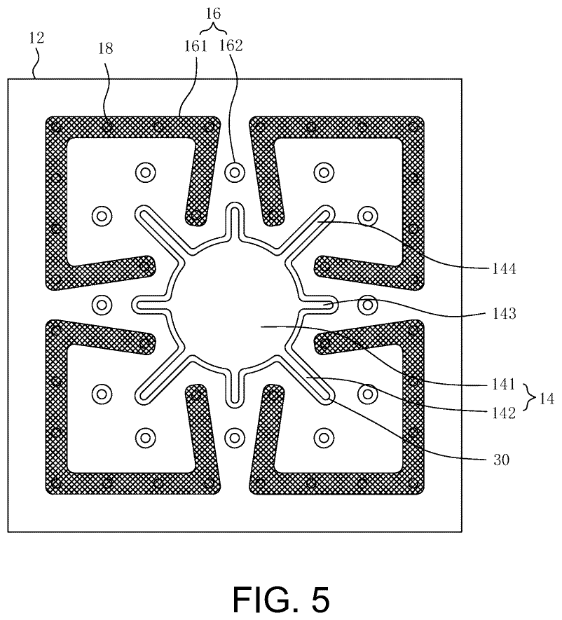

Please refer to FIG. 5. FIG. 5 is a schematic morphology view of a horizontal plane projection of a light emitting diode provided by the second embodiment of the disclosure. Compared with the light emitting diode of the first embodiment shown in FIG. 2, the main difference of this embodiment is that part of the surrounding electrode 161 close to the long extension electrode 144 has an inclination angle, and the part is inclined toward the interior of the surrounding electrode 161 rather than being horizontal. Two independent bulk electrodes 162 are further provided in the interior of each surrounding electrode 161. In this way, the operating voltage of the light emitting diode can be effectively reduced, the ESD protection performance can be improved, and the current expansion performance in the near field can be improved, thereby the overall performance and quality of the light emitting diode are improved.

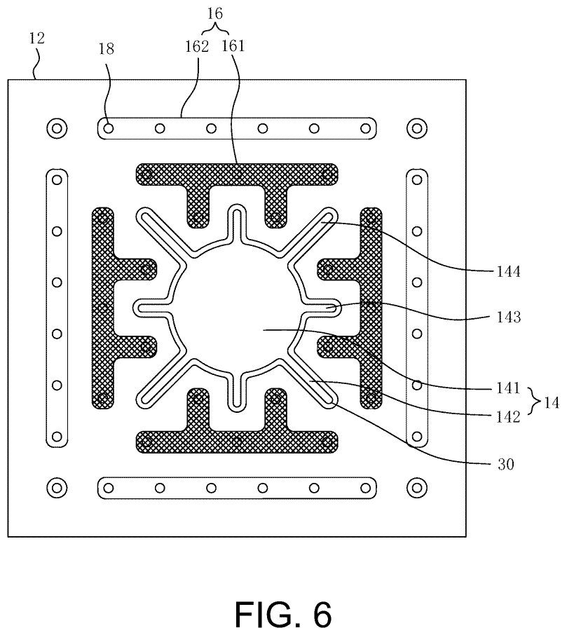

Please refer to FIG. 6. FIG. 6 is a schematic morphology view of a horizontal plane projection of a light emitting diode provided by the third embodiment of the disclosure. Compared with the light emitting diode of the first embodiment shown in FIG. 2, the main difference of this embodiment is that the first projection of the surrounding electrode 161 on the horizontal plane is in a π shape rather than the hook shape. Moreover, the surrounding electrode 161 surrounds the short extension electrode 143, and four large bulk electrodes 162 are provided correspondingly on the four sides 32 of the epitaxial structure 12. However, there is still a portion of the surrounding electrode 161 between two adjacent extension electrodes 142 (such as the long extension electrode 144 and the short extension electrode 143), and the surrounding electrode 161 still protrudes from the connection line between the terminal ends 30 of the two adjacent extension electrodes 142. In this way, the operating voltage of the light emitting diode can be effectively reduced, the ESD protection performance can be improved, and the current expansion performance in the near field can be improved, thereby the overall performance and quality of the light emitting diode are improved.

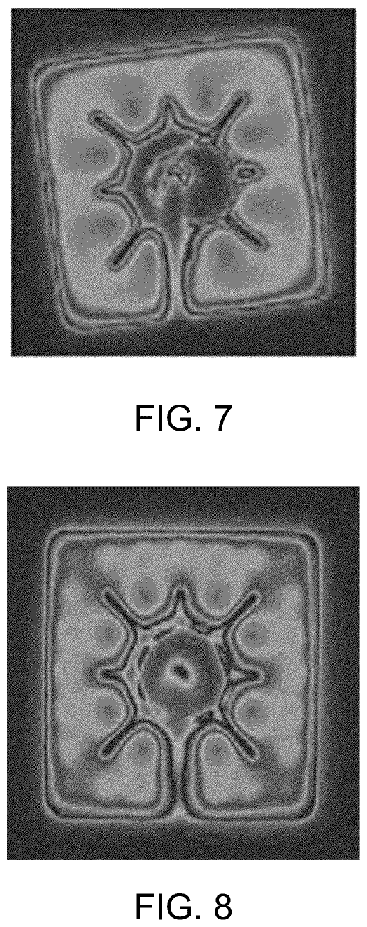

Please refer to FIG. 7 and FIG. 8. FIG. 7 is a schematic view of current expansion of the light emitting diode of the disclosure under a near-field microscope. FIG. 8 is a schematic view of current expansion of the conventional light emitting diode under a near-field microscope. Comparing FIG. 7 and FIG. 8, we may see that the light colors in FIG. 7 are almost evenly distributed, indicating that the current expansion is more uniform; and there are more dark areas at the outer edge and corners in FIG. 8, especially along the outward extension direction of the extension electrode 142, in which the outward conductivity of the current is poor, resulting in uneven current expansion, thereby the photoelectric quality and overall performance of the light emitting diode is reduced.

An embodiment of the disclosure further provides a light emitting device, which adopts the light emitting diode provided in any of the above embodiments.

A light emitting diode and a light emitting device provided by an embodiment of the disclosure adopt the manner that the surrounding electrode 161 surrounds the extension end 30 of the extension electrode 142, and the manner can effectively reduce the operating voltage of the light emitting diode, improve the ESD protection performance thereof, and improve the current expansion performance thereof in the near field, thereby the overall performance and quality of the light emitting diode are improved.

What is claimed is:

1. A light emitting diode, comprising:
an epitaxial structure comprising a P-type semiconductor layer, a light emitting layer, and an N-type semiconductor layer stacked sequentially;
an N-type electrode connected to the N-type semiconductor layer and comprising a starting electrode and X extension electrodes, X≥2 and X is a positive integer, the X extension electrodes are connected to the starting electrode, and the X extension electrodes are spaced apart along an edge of the starting electrode; and
a transparent conductive electrode connected to the P-type semiconductor layer;
wherein the transparent conductive electrode is a distributed electrode and comprises Y surrounding electrodes independent to each other, Y≥2 and Y is a positive integer, Y≤X, and a first projection of each of the surrounding electrodes on a horizontal plane surrounds a second projection of an extension end of a corresponding extension electrode on the horizontal plane.

2. The light emitting diode according to claim 1, wherein a portion of a corresponding surrounding electrode is between two adjacent extension electrodes.

3. The light emitting diode according to claim 2, wherein a line segment connecting the extension ends of the two adjacent extension electrodes is defined as a connection line, and a distance of the corresponding surrounding electrode protruding from the connection line is in a range of 10 μm to 20 μm.

4. The light emitting diode according to claim 1, wherein the transparent conductive electrode is located on a side of the P-type semiconductor layer away from the light emitting layer, and the N-type electrode is located on a side of the N-type semiconductor layer away from the light emitting layer.

5. The light emitting diode according to claim 4, wherein the light emitting diode further comprises a substrate, a blocking layer, a metal reflection layer, a P-type electrode and an insulation layer, the blocking layer covers part of the transparent conductive electrode, the metal reflection layer covers the blocking layer and the transparent conductive electrode, the substrate is disposed on a side of the metal reflection layer away from the blocking layer, the P-type electrode is disposed on a side of the substrate away from the metal reflection layer, and the insulation layer encapsulates the epitaxial structure and the N-type electrode.

6. The light emitting diode according to claim 5, wherein a material of the metal reflection layer comprises at least one selected from a group comprising Ag, Au, and Al.

7. The light emitting diode according to claim 1, wherein a horizontal projection area of the transparent conductive electrode is 10% to 30% of a horizontal projection area of the epitaxial structure.

8. The light emitting diode according to claim 1, wherein a third projection of the starting electrode on the horizontal plane is located at a center of a fourth projection of the epitaxial structure on the horizontal plane, and the third projection is quasicircular.

9. The light emitting diode according to claim 1, wherein the X extension electrodes comprise X1 short extension electrodes and X2 long extension electrodes, both X1 and X2 are positive integers, X=X1+X2, and a length of the long extension electrode is greater than a length of the short extension electrode.

10. The light emitting diode according to claim 9, wherein a shortest distance between the long extension electrode and the surrounding electrode is in a range of 15 μm to 25 μm.

11. The light emitting diode according to claim 9, wherein both X1 and X2 are greater than or equal to 2, and one short extension electrode is between two adjacent long extension electrodes.

12. The light emitting diode according to claim 11, wherein the epitaxial structure has 4 sides, and the 4 sides are sequentially connected end to end to form 4 connection points, X1 and X2 are equal to 4, the four short extension electrodes respectively extend correspondingly to midpoints of the four sides of the epitaxial structure, and the four long extension electrodes respectively extend correspondingly to the four connection points.

13. The light emitting diode according to claim 11, wherein the first projection is in a hook shape, and a projection of the long extension electrode on the horizontal plane reaches deep into an interior of the first projection in the hook shape.

14. The light emitting diode according to claim 13, wherein a reaching distance of the long extension electrode reaching into the first projection is 40% to 70% of the length of the long extension electrode.

15. The light emitting diode according to claim 1, wherein a side length of the light emitting diode is in a range of 150 μm to 300 μm.

16. A light emitting device, wherein the light emitting device adopts the light emitting diode according to claim 1.

17. A light emitting device, wherein the light emitting device adopts the light emitting diode according to claim 2.

18. A light emitting device, wherein the light emitting device adopts the light emitting diode according to claim 3.

19. A light emitting device, wherein the light emitting device adopts the light emitting diode according to claim 4.

20. A light emitting device, wherein the light emitting device adopts the light emitting diode according to claim 5.
